(19) United States
(12) Patent Application Publication
(10) Pub. No.: US 2026/0255752 A1
(43) Pub. Date: Aug. 27, 2026

(54) Display Panel, Display Apparatus, and Method for Manufacturing Display Panel

(71) Applicants: BOE MLED Technology Co., Ltd., Beijing (CN); BOE TECHNOLOGY GROUP CO., LTD., Chaoyang District, Beijing (CN)

(72) Inventors: Yuxuan Bai, Beijing (CN); Fan Yang, Beijing (CN); Qi Qi, Beijing (CN); Yuyang Li, Beijing (CN); Pengwei Wang, Beijing (CN)

(21) Appl. No.: 18/710,777

(22) PCT Filed: Mar. 28, 2023
(86) PCT No.: PCT/CN2023/084536

§ 371 Date: May 16, 2024

(30) Foreign Application Priority Data
Mar. 28, 2022 (WO) PCT/CN2022/083506

(51) Int. Cl. H10H 29/49; H10H 20/831; H10H 29/01

(52) U.S. Cl. CPC H10H 29/49; H10H 20/8312; H10H 29/012; H10H 29/0364

(57) ABSTRACT

A display panel includes a backplane, a plurality of connecting lines and a protective layer. The backplane includes a first main surface and a second main surface, and side surfaces connecting the first main surface and the second main surface. At least one side surface is a selected side surface protruding from a first reference plane. The selected side surface is composed by a plurality of first sub-surfaces connected in sequence. The plurality of first sub-surfaces have the same curvature; or each first sub-surface is a plane; or a part of first sub-surfaces are planes, and another part of first sub-surface are curved surfaces. The plurality of connecting lines are provided side by side and at intervals. The protective layer is at least provided on the side surface and regions of the first main surface and the second main surface proximate to the selected side surface.

### CROSS-REFERENCE TO RELATED APPLICATIONS

This application is the United States national phase of International Patent Application No. PCT/CN2023/084536, filed Mar. 28, 2023, and claims priority to International Patent Application No. PCT/CN2022/083506, filed Mar. 28, 2022, the disclosures of which are hereby incorporated by reference in their entireties.

### BACKGROUND OF THE INVENTION

### Field of the Invention

The present disclosure relates to the field of display technologies, and in particular, to a display panel, a display apparatus and a method for manufacturing the display panel.

### Description of Related Art

As a new generation of display technology, MLEDs include mini light-emitting diodes (mini LEDs) and micro light-emitting diodes (micro LEDs). Compared with a traditional LED, each mini/micro LED die has a small volume. A display apparatus using mini/micro LEDs as light-emitting devices has high contrast, long life, low power consumption, and other characteristics, and thus technologies related thereto have become one of current research hotspots.

### SUMMARY OF THE INVENTION

In an aspect, a display panel is provided. The display panel includes a backplane, a plurality of connecting lines and a protective layer. The backplane includes a first main surface and a second main surface that are opposite, and a plurality of side surfaces connecting the first main surface and the second main surface. At least one side surface in the plurality of side surfaces is a selected side surface. The selected side surface protrudes from a first reference plane, and the first reference plane is a plane and is connected to and adjacent to the first main surface and the second main surface. The selected side surface is composed of a plurality of first sub-surfaces connected in sequence. The plurality of first sub-surfaces have same curvature; alternatively, each first sub-surface in the plurality of first sub-surfaces is a plane; alternatively, a part of first sub-surfaces in the plurality of first sub-surfaces are planes, and another part of first sub-surfaces in the plurality of first sub-surfaces are curved surfaces. The plurality of connecting lines are arranged side by side and at intervals. Each connecting line in the plurality of connecting lines includes a first segment of line, a second segment of line and a third segment of line that are connected in sequence. First segment of lines of the plurality of connecting lines are disposed on the first main surface, second segment of lines of the plurality of connecting lines are disposed on the selected side surface, and third segment of lines of the plurality of connecting lines are disposed on the second main surface. The protective layer is at least disposed on the selected side surface and regions of the first main surface and the second main surface proximate to the selected side surface.

In some embodiments, the selected side surface is a curved surface, and a central angle corresponding to the curved surface is in a range of 30° to 35°, inclusive.

In some embodiments, each first sub-surface in the plurality of first sub-surfaces is a plane. The selected side surface includes at least four planes connected in sequence. A plane connected to the first main surface is a first connection plane, and a plane connected to the second main surface is a second connection plane. An angle between the first connection plane and the adjacent first main surface is greater than 135°, an angle between two adjacent planes of the selected side surface is greater than 135°, and an angle between the second connection plane and the adjacent second main surface is greater than 135°.

In some embodiments, the selected side surface is axisymmetric about a second reference plane, the second reference plane is parallel to the first main surface, and a distance between the second reference plane and the first main surface is equal to a distance between the second reference plane and the second main surface.

In some embodiments, a maximum vertical distance between an intersection line of the selected side surface and the second reference plane and the first reference plane is in a range of 40 μm to 50 μm, inclusive.

In some embodiments, a ratio of areas of any two first sub-surfaces is in a range of 0.5 to 2, inclusive.

In some embodiments, the plurality of side surfaces are all selected side surfaces.

In some embodiments, each two adjacent side surfaces is a group of side surfaces, and two side surfaces of at least one group of side surfaces are connected by a transition side surface. The transition side surface is composed of a plurality of second sub-surfaces connected in sequence. The plurality of second sub-surfaces have same curvature; alternatively, each second sub-surface in the plurality of second sub-surfaces is a plane; alternatively, a part of second sub-surfaces in the plurality of second sub-surfaces are planes, and another part of second sub-surfaces in the plurality of second sub-surfaces are curved surfaces.

In some embodiments, a ratio of areas of any two second sub-surfaces is in a range of 0.5 to 2, inclusive.

In some embodiments, a shape of an orthographic projection of the transition side surface on a plane where the first main surface is located is a plurality of sub-segments connected in sequence. Each sub-segment in the plurality of sub-segments is a curved segment; alternatively, each sub-segment in the plurality of sub-segments is a line segment; alternatively, a part of sub-segments in the plurality of sub-segments are curved segments, and another part of sub-segments in the plurality of sub-segments are line segments.

In some embodiments, a shape of the transition side surface obtained by taking a cross-section perpendicular to the first main surface and along a diagonal line of the first main surface is a plurality of sub-segments connected in sequence. Each sub-segment in the plurality of sub-segments is a curved segment; alternatively, each sub-segment in the plurality of sub-segments is a line segment; alternatively, a part of sub-segments in the plurality of sub-segments are curved segments, and another part of sub-segments in the plurality of sub-segments are line segments.

In some embodiments, the protective layer further covers the plurality of connecting lines, and the protective layer is disposed on a side of the plurality of connecting lines away from the backplane.

In some embodiments, a thickness of the protective layer is in a range of 1.7 μm to 1.8 μm, inclusive.

In some embodiments, the display panel further includes a plurality of first electrodes disposed on the first main surface and a plurality of light-emitting devices disposed on the first main surface of the backplane. The plurality of first electrodes are disposed proximate to the selected side surface, and each connecting line is electrically connected to a first electrode in the plurality of first electrodes. The plurality of light-emitting devices are electrically connected to the plurality of first electrodes.

In some embodiments, the display panel further includes a plurality of second electrodes disposed on the second main surface of the backplane. The plurality of second electrodes are configured to be electrically connected to a driver chip or a flexible circuit board. Each connecting line in the plurality of connecting lines is electrically connected to a second electrode in the plurality of second electrodes.

In another aspect, a display apparatus is provided. The display apparatus includes the display panel as described in any of the above embodiments and a driver chip. The driver chip is disposed on the second main surface of the backplane in the display panel. The driver chip is electrically connected to the plurality of connecting lines in the display panel.

In yet another aspect, a method for manufacturing a display panel is provided. The manufacturing method includes following steps. An initial backplane is provided; the initial backplane includes a first main surface and a second main surface that are opposite, and a plurality of initial side surfaces connecting the first main surface and the second main surface; and the plurality of initial side surfaces are perpendicular or substantially perpendicular to the first main surface and the second main surface.

The plurality of initial side surfaces are ground to form a plurality of side surfaces; at least one side surface in the plurality of side surfaces is a selected side surface, the selected side surface protrudes from a first reference plane, and the first reference plane is a plane and is connected to and adjacent to the first main surface and the second main surface; the selected side surface is composed of a plurality of first sub-surfaces connected in sequence; the plurality of first sub-surfaces have same curvature; alternatively, each first sub-surface in the plurality of first sub-surfaces is a plane; alternatively, a part of first sub-surfaces in the plurality of first sub-surfaces are planes, and another part of first sub-surfaces in the plurality of first sub-surfaces are curved surfaces.

A plurality of connecting lines is formed on the first main surface, the selected side surface and the second main surface; the plurality of connecting lines are disposed side by side and at intervals; each connecting line in the plurality of connecting lines includes a first segment of line, a second segment of line and a third segment of line that are connected in sequence; first segment of lines of the plurality of connecting lines are disposed on the first main surface, second segment of lines of the plurality of connecting lines are disposed on the selected side surface, and third segment of lines of the plurality of connecting lines are disposed on the second main surface.

A protective layer is formed; and the protective layer is at least disposed on the selected side surface and regions of the first main surface and the second main surface proximate to the selected side surface.

In some embodiments, in a process of grinding the plurality of initial side surfaces, a boundary edge of two adjacent initial side surfaces in at least one group of initial side surfaces is ground to form a transition side surface. Two adjacent side surfaces are connected by the transition side surface, and the transition side surface is composed of a plurality of second sub-surfaces connected in sequence. The plurality of second sub-surfaces have same curvature; alternatively, each second sub-surface in the plurality of second sub-surfaces is a plane; alternatively, a part of second sub-surfaces in the plurality of second sub-surfaces are planes, and another part of second sub-surfaces in the plurality of second sub-surfaces are curved surfaces.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display panel, in accordance with some embodiments;

FIG. 2A is a sectional view of a display panel, in accordance with some embodiments;

FIG. 2B is a sectional view of another display panel, in accordance with some embodiments;

FIG. 2C is a sectional view of another display panel, in accordance with some embodiments;

FIG. 2D is a sectional view of another display panel, in accordance with some embodiments;

FIG. 2E is a scanning electron microscope (SEM) enlarged structural diagram of a protective layer of a display panel, in accordance with some embodiments;

FIG. 2F is a SEM enlarged structural diagram of a protective layer of a display panel, in accordance with some embodiments;

FIG. 2G is a tiled structural diagram of a display panel, in accordance with some embodiments;

FIG. 3A is a sectional view of yet another display panel, in accordance with some embodiments;

FIG. 3B is a sectional view of yet another display panel, in accordance with some embodiments;

FIG. 3C is a sectional view of yet another display panel, in accordance with some embodiments;

FIG. 4A is a sectional view of yet another display panel, in accordance with some embodiments;

FIG. 4B is a sectional view of yet another display panel, in accordance with some embodiments;

FIG. 5 is a three-dimensional structural diagram of a display panel, in accordance with some embodiments;

FIG. 6A is a partial enlarged view of a display panel shown in FIG. 5, in accordance with some embodiments;

FIG. 6B is another partial enlarged view of a display panel shown in FIG. 5, in accordance with some embodiments;

FIG. 6C is another partial enlarged view of a display panel shown in FIG. 5, in accordance with some embodiments;

FIG. 7A is a partial enlarged view of an orthographic projection of a transition side surface of a display panel on the first main surface, in accordance with some embodiments;

FIG. 7B is a partial enlarged view of an orthographic projection of a transition side surface of another display panel on the first main surface, in accordance with some embodiments;

FIG. 7C is a partial enlarged view of an orthographic projection of a transition side surface of another display panel on the first main surface, in accordance with some embodiments;

FIG. 8A is a sectional view showing a structure of a transition side surface of a display panel taken along a line perpendicular to a diagonal line of a first main surface, in accordance with some embodiments;

FIG. 8B is a sectional view showing a structure of a transition side surface of another display panel taken along a line perpendicular to a diagonal line of a first main surface, in accordance with some embodiments;

FIG. 8C is a sectional view showing a structure of a transition side surface of another display panel taken along a line perpendicular to a diagonal line of a first main surface, in accordance with some embodiments;

FIG. 9 is a sectional view of yet another display panel, in accordance with some embodiments;

FIG. 10 is a sectional view of yet another display panel, in accordance with some embodiments;

FIG. 11 is a structural diagram of a display apparatus, in accordance with some embodiments;

FIG. 12 is a flowchart of a method for manufacturing a display panel, in accordance with some embodiments;

FIG. 13A is a working procedure diagram of a method for manufacturing a display panel, in accordance with some embodiments;

FIG. 13B is another working procedure diagram of a method for manufacturing a display panel, in accordance with some embodiments;

FIG. 13C is another working procedure diagram of a method for manufacturing a display panel, in accordance with some embodiments;

FIG. 13D is another working procedure diagram of a method for manufacturing a display panel, in accordance with some embodiments;

FIG. 13E is another working procedure diagram of a method for manufacturing a display panel, in accordance with some embodiments; and

FIG. 14 is a three-dimensional structural diagram of a side surface of a backplane before and after grinding in a method for manufacturing a display panel, in accordance with some embodiments.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. The term “connection” should be understood in a broad sense. For example, the “connection” may be a fixed connection, a detachable connection, or of an integrated structure; it may be a direct connection or an indirect connection by an intermediate medium. The term “coupled” indicates, for example, that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude apparatuses that are applicable to or configured to perform additional tasks or steps.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

At present, mini light-emitting diode (mini LED) display panels and micro light-emitting diode (micro LED) display panels generally use transparent glass or organic glass as backplane base materials. During manufacturing the display panel, the right-angled edges of the backplane base material are usually ground to form chamfered surfaces, so as to reduce stress on the edges. However, it is found by inventors of the present disclosure that such a design still causes the following problems: a protective structure formed on a surface of the right-angled edges is thinner than that formed at other positions, and devices in the display panel are prone to corrosion by moisture and oxygen to cause poor wiring and affect normal transmission of signals, which thus affects the normal operation of the display panel; moreover, during transportation of the product, the chamfered surface is still prone to collision and edge chipping and corner chipping, which seriously affects quality of the product and an overall pass rate, resulting in generation of a large amount of consumables and an increase in production costs.

In light of this, some embodiments of the present disclosure provide a display panel, a display apparatus, and a method for manufacturing a display panel. The existing chamfer structure is changed. As a result, the formed protective structure has a uniform thickness at this position, thereby improving yield of the display panel. In addition, edges and side surface(s) of the display panel may have a smooth transition, thereby reducing an edge chipping rate of the product, and further improving yield and quality of the product.

The display panel, the display apparatus and the method for manufacturing the display panel provided by the present disclosure are introduced below respectively.

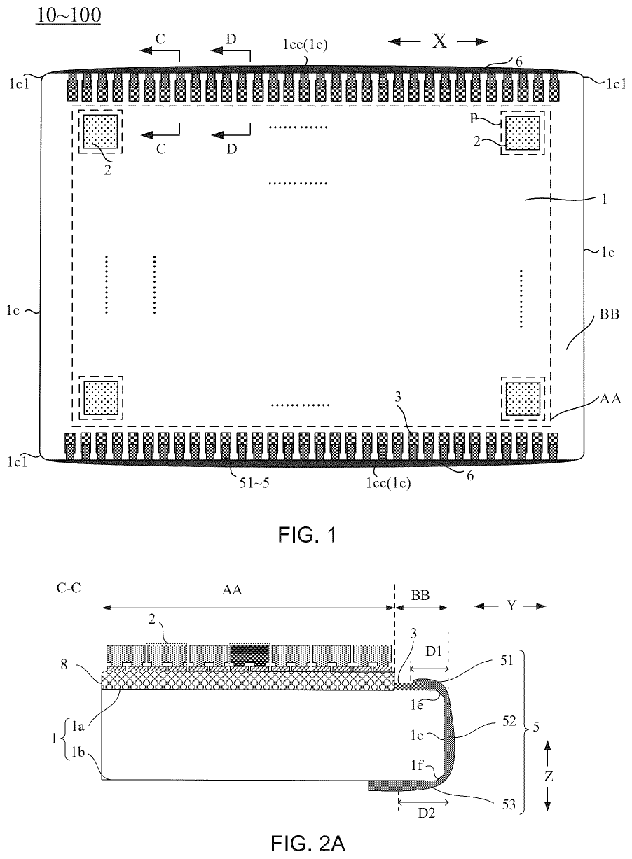

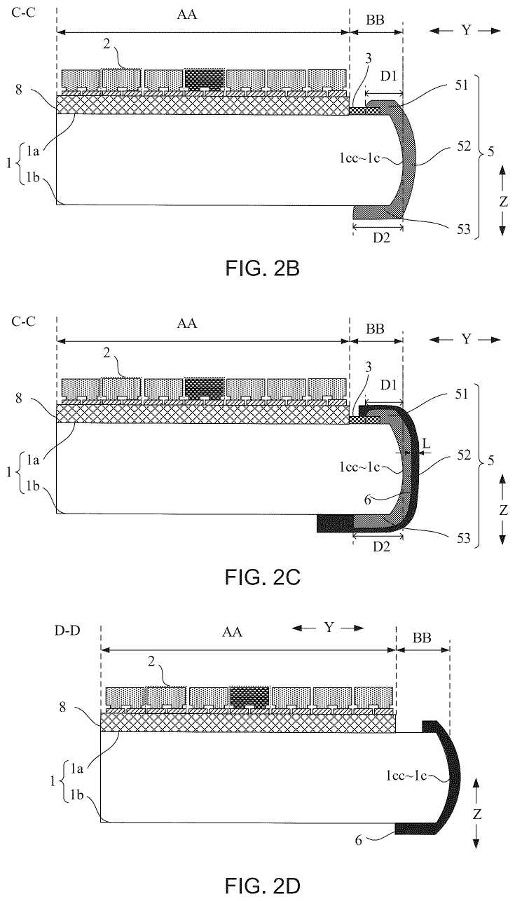

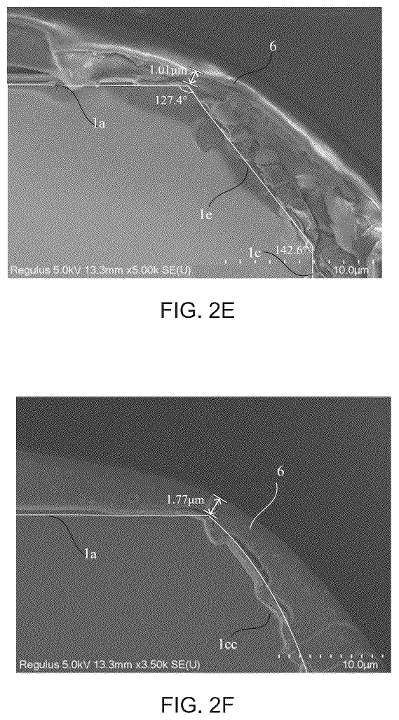

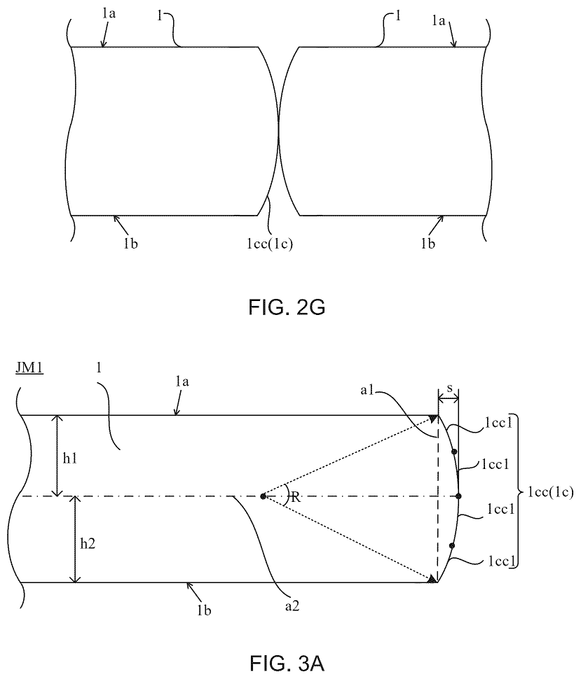

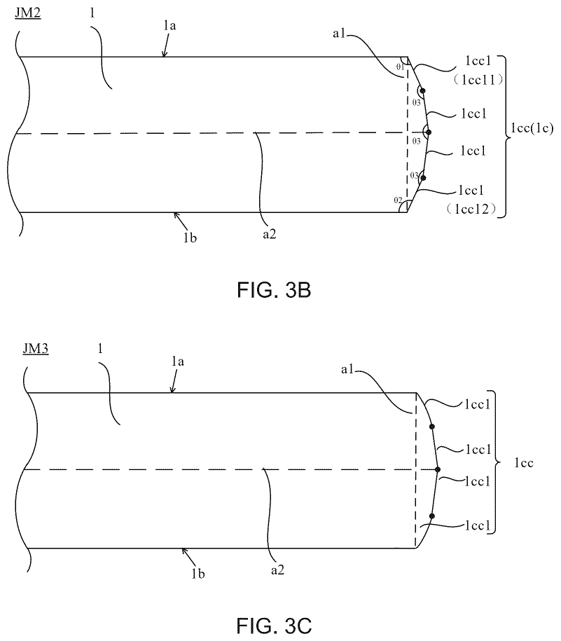

In the embodiments of the present disclosure, FIG. 1 is a plane structure diagram of the display panel 10. FIGS. 2A to 2C are sectional views of display panels in different conditions obtained by taking along section lines CC according to FIG. 1. FIG. 2D is a sectional view of the display panel obtained by taking along a section line DD according to FIG. 1. In each of the backplanes 1 shown in FIGS. 3A to 8C, first electrodes, light-emitting devices, wiring on side surfaces and other components are omitted to facilitate expansion and description of the structure of the backplane 1.

Some embodiments of the present disclosure provide a display panel 10. As shown in FIG. 1, the display panel 10 includes a display region AA and a peripheral region BB provided on at least one side of the display region AA. For example, the peripheral region BB may be located on one side, two sides or three sides of the display region AA. Alternatively, the peripheral region BB may be provided around the display region AA.

In some embodiments, as shown in FIGS. 2B and 2C, the display panel 10 includes a backplane 1, a plurality of light-emitting devices 2, a plurality of first electrodes 3 and a plurality of connecting lines 5. The backplane 1 includes a first main surface 1a and a second main surface 1b, and a plurality of side surfaces 1c connecting the first main surface 1a and the second main surface 1b. The plurality of light-emitting devices 2 and the plurality of first electrodes 3 are provided on the first main surface 1a of the backplane 1. The plurality of first electrodes 3 are arranged at intervals in a first direction X. The plurality of first electrodes 3 are provided proximate to side surfaces 1c (e.g., selected side surface(s) 1cc) relative to the plurality of light-emitting devices 2. The plurality of first electrodes 3 are electrically connected to the plurality of light-emitting devices 2.

In some embodiments, an insulating layer is provided between the plurality of first electrodes 3 and the first main surface 1a of the backplane 1, and a film layer structure such as a driving circuit layer 8 is provided between the plurality of light-emitting devices 2 and the first main surface 1a of the backplane 1. The driving circuit layer 8 includes a plurality of signal lines. The plurality of first electrodes 3 are electrically connected to the plurality of light-emitting devices 2 by signal lines in the driving circuit layer 8. The signal lines are configured to transmit signals to the plurality of light-emitting devices 2 to drive the plurality of light-emitting devices 2 to emit light.

For example, as shown in FIG. 1, the display panel 10 includes sub-pixels P of at least three colors, and the sub-pixels of the plurality of colors include a sub-pixel of a first color, a sub-pixel of a second color and a sub-pixel of a third color. The first color, the second color and the third color are three primary colors (e.g., red, green and blue). For example, each sub-pixel P includes at least one light-emitting device.

For example, the light-emitting device 2 includes, but is not limited to, an organic light-emitting diode (OLED), a mini light-emitting diode (mini LED), a micro light-emitting diode (micro LED), or the like.

In some examples, as shown in FIG. 1, the mini LEDs or the micro LEDs are used as light-emitting devices 2. Compared with traditional LEDs, the light-emitting device 2 occupies a smaller volume and has a smaller die, and within the same screen size, a density of light sources within a unit area is higher and a unit size of the light source is smaller. Therefore, a precise local control of the light-emitting devices 2 may be achieved, and the uniformity of the display brightness may be ensured, thereby ensuring the display quality of the display panel 10.

The first main surface 1a of the backplane 1 is a front surface of the backplane 1 and corresponds to a display surface of the display panel 10. The second main surface 1b of the backplane 1 is a back surface of the backplane and corresponds to a non-display surface of the display panel 10.

For example, the material of the backplane 1 is a rigid material such as glass, quartz or plastic.

In some embodiments, the plurality of connecting lines 5 are arranged side by side and at intervals. Referring to FIGS. 2A to 2C, each connecting line 5 in the plurality of connecting lines 5 includes a first segment of line 51, a second segment of line 52 and a third segment of line 53 connected in sequence. The first segment of lines 51 are disposed on the first main surface 1a, the second segment of lines 52 are disposed on at least one side surface in the plurality of side surfaces 1c, and the third segment of lines 53 are disposed on the second main surface 1b. Each connecting line 5 is electrically connected to a first electrode 3 in the plurality of first electrodes 3.

It will be noted that the second segment of lines 52 are disposed on at least one side surface 1c in the plurality of side surfaces 1c, which means that the second segment of lines 52 may be provided on one side surface 1c, two side surfaces 1c, three side surfaces 1c or four side surfaces 1c. The number of the plurality of connecting lines 5 is equal to the number of the plurality of first electrodes 3. Each connecting line 5 passes through the side surface 1c from the second main surface 1b to be electrically connected to a first electrode 3, thereby realizing electrical connection of the first electrode 3 from the first main surface 1a of the backplane 1 to the second main surface 1b opposite to the first main surface 1a.

In some embodiments, as shown in FIGS. 1 and 2C, the display panel further includes a protective layer 6. The protective layer 6 is at least disposed on a side surface 1c, and regions of the first main surface 1a and the second main surface 1b proximate to the side surface 1c.

It can be understood that the protective layer 6 is configured to protect the side surface 1c, and regions of the first main surface 1a and the second main surface 1b proximate to the side surface 1c, so as to avoid collision and damage of the side surface during movement or assembly.

In some embodiments, as shown in FIG. 2C, the protective layer 6 covers the plurality of connecting lines 5, and the protective layer 6 is disposed on a side of the plurality of connecting lines 5 away from the backplane 1. That is, the protective layer 6 is provided on the side surface on which the plurality of connecting lines 5 are formed.

For example, referring to FIGS. 2D and 2C, the protective layer 6 fills gaps between the plurality of connecting lines 5 and cover surfaces of the plurality of connecting lines 5. The protective layer 6 is configured to protecting the plurality of connecting lines 5, and plays a role of electrical insulation and anti-corrosion against moisture and oxygen, thereby preventing the plurality of connecting lines 5 from peeling, disconnection and oxidation due to external damage.

In some examples, the material of the protective layer 6 is an insulating material with high corrosion resistance and high adhesion. For example, the material of the protective layer 6 is an organic material such as resin or ink. The color of the protective layer 6 may be transparent white or transparent dark color (e.g., green, black, brown, or rufous). The ink has high hardness and good corrosion resistance, and may protect the plurality of connecting lines 5.

In the related art, as mentioned above, with reference to FIG. 2A, the backplane 1 includes a first main surface 1a and a second main surfaces 1b that are opposite, and a plurality of side surfaces 1c connecting the first main surface 1a and the second main surfaces 1b. The plurality of side surfaces 1c are perpendicular to the first main surface 1a or the second main surface 1b. A chamfer is formed at an edge where the side surface 1c and the first main surface 1a are connected, that is, there is a chamfer surface 1e between the side surface and the first main surface. A chamfer is formed at an edge where the side surface 1c and the second main surface 1b are connected, that is, there is a second chamfer surface if between the side surface 1c and the second main surface 1b. The area of the first chamfer surface 1e is S₁, the area of the second chamfer surface 1f is S₂, the area of the side surface 1c is S₃, and S₁, S₂ and S₃ satisfy the following relationship: 0.9<S₃/(S₁+S₂+S₃)<1, and 0.95<S₂/S₃<1.05. The plurality of connecting lines 5 are located on at least one side surface, and the first chamfer surface 1e and the second chamfer surface 1f that are connected to the side surface. The protective layer covers the plurality of connecting lines 5 and is located on the first chamfer surface 1e, the side surface 1c and the second chamfered surface 1f. In FIG. 2A, for information related to the plurality of light-emitting devices 2, the plurality of first electrodes 3, the plurality of connecting lines 5 and the protective layer 6 included in the display panel, reference may be made to the description of the display panel shown in any of FIGS. 2B and 2C.

In a case shown in FIG. 2A, the areas of the first chamfered surface 1e and the second chamfered surface 1f are much smaller than the area of the side surface 1c. Therefore, there are still obvious edges between the first main surface 1a and the side surface 1c and between the second main surface 1b and the side surface 1c. In a process of forming the protective layer by pad printing, the edges need to be pad printed multiple times to meet the thickness requirement. In addition, the protective layer has a smaller thickness at the edges than at other positions, and is prone to being scratched to expose the internal connecting lines 5 during manual operations, thereby causing the risk of being scratched and corrosion of the connecting lines 5. Moreover, during transportation of the product, the edges are prone to collision and edge chipping and corner chipping, thereby affecting the yield of the display panel.

In some embodiments of the display panel provided by the present disclosure, with reference to FIGS. 2B to 2D, at least one side surface in the plurality of side surfaces is called a selected side surface 1cc. As shown in FIGS. 3A to 3C, the selected side surface 1cc protrudes from a first reference plane a1, the first reference plane a1 is a plane and is connected to and adjacent to the first main surface 1a and the second main surface 1b. The selected side surface 1cc is composed of a plurality of first sub-surfaces 1cc1 connected in sequence. The plurality of first sub-surfaces 1cc1 have the same curvature. Alternatively, each first sub-surface 1cc1 in the plurality of first sub-surfaces 1cc1 is a plane. Alternatively, a part of first sub-surfaces 1cc1 in the plurality of first sub-surfaces 1cc1 are planes, and another part of first sub-surfaces 1cc1 in the plurality of first sub-surfaces 1cc1 are curved surfaces.

The selected side surface 1cc includes a plurality of first sub-surfaces 1cc1. The plurality of first sub-surfaces 1cc1 are connected in sequence in a direction from the first main surface 1a to the second main surface 1b. The plurality of first sub-surfaces 1cc1 may all be curved surfaces or all be planes. Alternatively, a part of the plurality of first sub-surfaces 1cc1 are planes, and another part of the plurality of first sub-surfaces 1cc1 are curved surfaces.

In some embodiments, a ratio of areas of any two first sub-surfaces is in a range of 0.5 to 2, inclusive; further, it may be in a range of 0.9 to 1.1, inclusive.

In some embodiments, the plurality of connecting lines 5 are disposed on the selected side surface 1cc, and the protective layer 6 is disposed on the selected side surface to cover the plurality of connecting lines 5.

It will be noted that FIGS. 3A to 3C are each a sectional view of the backplane 1 in a direction perpendicular to the first main surface 1a and perpendicular to a boundary edge of the first main surface and the selected side surface 1cc, and the sections corresponding to the three cases are JM1, JM2 and JM3, respectively. That is, FIGS. 3A to 3C are each a structural diagram of the backplane 1 in the sectional view of the display panel 10 obtained according to the section line CC in FIG. 1, where the first reference plane a1 is perpendicular to the first main surface 1a and the second main surface 1b, two ends of the first reference plane a1 are adjacent to and connected to the first main surface 1a and the second main surface 1b, respectively, and the selected side surface 1cc protrudes toward a side away from the first main surface 1a and the second main surface 1b relative to the first reference plane a1. The first reference plane a1 is only used as a reference convenient for illustrating the protrusion direction of the selected side surface, and the first reference plane a1 is not a solid surface.

For example, referring to FIG. 3A, since the selected side surface 1cc is composed of the plurality of first sub-surfaces 1cc1 connected in sequence, and the plurality of first sub-surfaces 1cc1 have the same curvature, the plurality of first sub-surfaces 1cc1 are all curved surfaces. The orthographic projection of the selected side surface 1cc on the section JM1 is a plurality of curved segments with the same curvature, and the plurality of curved segments are connected in sequence to form a smooth curve, that is, the orthographic projection of the plurality of curved segments on the section is in a curved shape. For example, the number of the plurality of first sub-surfaces 1cc1 is two, three, four or countless. Since the plurality of first sub-surfaces 1cc1 all have the same curvature, regardless of the number of the plurality of first sub-surfaces, the plurality of first sub-surfaces 1cc1 may form a smooth curved surface structure. In FIG. 3A, the description is made by considering an example where the selected side surface includes four first sub-surfaces 1cc1. In this way, the first main surface 1a and the second main surface 1b may be smoothly connected by the selected side surface. Compared with a case that the first main surface 1a and the second main surface 1b are connected directly by a plane in the related art, the selected side surface is rather smooth overall, so that collision caused by excessive concentration of stress on the edges may be reduced, thereby reducing the breakage rate of the display panel and enhancing the reliability of the display panel.

For example, referring to FIG. 3B, each first sub-surface 1cc1 in the plurality of first sub-surfaces 1cc1 is a plane, and the number of the first sub-surfaces 1cc1 is at least four. For example, the number of the first sub-surfaces 1cc1 in FIG. 3B is four. The four first sub-surfaces 1cc1 are connected in sequence. The orthographic projection of the selected side surface 1cc on the section JM2 is a plurality of straight line segments, and an included angle between two adjacent straight line segments is greater than 135°, that is, an included angle θ3 between the two adjacent first sub-surfaces 1cc1 is greater than 135°. In addition, an included angle θ1 between a first sub-surface 1cc1 connected to the first main surface 1a and the first main surface 1a is greater than 135°, and an included angle θ2 between a first sub-surface 1cc1 connected to the second main surface 1b and the second main surface 1b is greater than 135°. In this way, the greater the included angle between two adjacent planes, the smoother the transition between the two adjacent planes, and the smoother the whole of the selected side surface, thereby dispersing stress and reducing collision caused by excessive concentration of stress on the edges.

For example, referring to FIG. 3C, a part of the plurality of first sub-surfaces 1cc1 are planes, and another part of the plurality of first sub-surfaces 1cc1 are curved surfaces. For example, the number of the first sub-surfaces 1cc1 in FIG. 3C is four, two first sub-surfaces 1cc1 respectively connecting the first main surface 1a and the second main surface 1b are curved surfaces, and the other two first sub-surfaces 1cc1 are planes. For the orthographic projection of the selected side surface 1cc on the section JM3, a part thereof are curved segments, and another part thereof are straight line segments. In this way, the first main surface 1a and the second main surface 1b may also be connected in a smooth transition, thereby reducing collision caused by excessive concentration of stress on the edges.

The selected side surface 1cc of the backplane 1 is provided as above to make the transition of the selected side surface gentle, so as to reduce breakage during transportation of the product caused by excessive concentration of stress on the edges (an intersection line of the selected side surface and the first main surface, or an intersection line of the selected side surface and the second main surface) as much as possible. It is obtained through test by the inventors of the present disclosure that the breakage rate during transportation of the product is reduced from 0.3% to 0.04%. In addition, since the shape of the selected side surface is a curved surface or a curved-like surface, compared with a plane, when two display panels are tiled, the side profiles are also approximately curved. The adjacent selected side surfaces of two adjacent display panels have a small directly opposite area. Referring to FIG. 2G, FIG. 2G is a schematic diagram showing a structure of the two tiled display panels, and device structure(s) outside the selected side surface are omitted in this figure. It can be concluded from this figure that the two display panels are only in contact at the middle position, so that a contact area between the two display panels may be reduced, and thus collision damage during assembly may be reduced. It is obtained through experiments by the inventors of the present disclosure that the breakage rate during assembly of the product is reduced from 0.17% to 0.04%.

In some embodiments, referring to FIG. 2A, in a direction perpendicular to the selected side surface 1cc, such as a second direction Y in this figure, the thickness L of the protective layer 6 is not uniform everywhere, and the thickness L of the protective layer 6 at the middle is greater than the thickness L of the protective layer 6 at two sides. It will be noted that due to the manufacturing process (e.g., pad printing) for forming the protective layer 6, during formation by pad printing, the pad printing rubber head and the edge of the selected side surface has a small contact area, so that loss of the pad printing material may be caused easily, the pad printing material is not easy to be attached to the location, and multiple pad printing is required, resulting in a low production efficiency. Moreover, after the formation of the protective layer is completed, the thickness of the protective layer at the edge of the display panel 10 is relatively small. For example, as shown in FIG. 2E, after pad printing twice, the thickness of the protective layer at the edge between the first chamfered surface and the first main surface is only 1.01 μm. The protective layer at this location is easily scratched during subsequent operations, thereby resulting in the risk of scratch and corrosion of the connecting lines.

In the display panel provided by some above embodiments of the present disclosure, the selected side surface 1cc is provided as a curved surface or a structure infinitely close to a curved surface, and the protective layer is formed by pad printing. When the pad printing rubber head is in contact with the selected side surface (e.g., the boundary edge between the first main surface and the selected side surface) of the display panel 10, a volume of deformation of the pad printing rubber head may increase, that is, a contact area between the pad printing rubber head and the selected side surface increases. Further, it is easy to form the protective layer 6, so as to reduce the loss of the material and the number of pad printing, thereby increasing the life of the pad printing rubber head, improving production efficiency and saving production costs. Moreover, the thickness of the formed protective layer increases, so as to reduce the risk of exposing the connecting lines due to scratch of the protective layer, thereby improving the reliability of the display panel.

In some embodiments, the thickness L of the protective layer 6 is in a range of 1.7 μm to 1.8 μm, inclusive. It will be noted that the thickness of the protective layer 6 is an average value of the thickness of the protective layer 6 at various positions.

Based on the structure of the above selected side surface 1cc of smooth transition, when the protective layer 6 is formed and the pad printing rubber head is in contact with the selected side surface 1cc, the pad printing rubber head is prone to formation of a good contact with the selected side surface. Thus, the protective layer with sufficient thickness may be formed by few pad printing times. For example, as shown in FIG. 2F, after pad printing once, the thickness of the protective layer at the edge between the selected side surface and the first main surface may reach 1.77 μm, thereby meeting the thickness requirements of the protective layer.

In some embodiments, the greater the number of the plurality of first sub-surfaces included in the selected side surface, the closer the selected side surface to a curved surface, or the more curved the selected side surface, the smoother the whole of the selected side surface, and the less obvious the edge of the selected side surface, thereby being conducive to the formation of the protective layer and further reducing the breakage rate of the display panel.

In some embodiments, referring to FIG. 3A, the selected side surface 1cc is a curved surface, and a central angle R of the curved surface is in a range of 30° to 35°, inclusive.

It will be noted that the setting of the above central angle limits that in a case where the selected side surface is a curved surface, a degree and curvature of the curved surface protruding from the first reference plane may make the transition of the selected side surface 1cc rather smooth and make the selected side surface not excessively protruded, thereby facilitating the formation of the plurality of connecting lines, the protective layer and other structures, and being also conducive to subsequent tiling of the display panels.

In some embodiments, referring to FIG. 3B, each first sub-surfaces 1cc1 in the plurality of first sub-surfaces 1cc1 is a plane. The selected side surface 1cc includes at least four planes connected in sequence, a plane connected to the first main surface 1a is a first connection plane 1cc11, and a plane connected to the second main surface is a second connection plane 1cc12. An angle between the first connection plane 1cc11 and the adjacent first main surface 1a is greater than 135°, an angle between two adjacent planes of the selected side surface 1cc is greater than 135°, and an angle between the second connection plane 1cc12 and the adjacent second main surface 1b is greater than 135°.

For example, referring to FIG. 3B, the selected side surface 1cc includes at least four planes connected in sequence. The plane connected to the first main surface 1a is the first connection plane 1cc11, and the angle θ1 between the first connection plane 1cc11 and the adjacent first main surface 1a is greater than 135°. The plane connected to the second main surface is the second connection plane 1cc12, and the angle θ2 between the second connection plane 1cc12 and the adjacent second main surface 1b is greater than 135°. The angle θ3 between the two adjacent first sub-surfaces 1cc1 of the selected side surface 1cc is greater than 135°. The effect that can be achieved by the selected side surface 1cc is similar to that of the selected side surface 1cc shown in FIGS. 3A and 3C, and details are not described again here. It can be understood that the angle θ1, the angle θ2, and the angle θ3 each refer to a dihedral angle of any two surfaces toward the first reference plane a1.

In some embodiments, referring to FIG. 3A, the selected side surface 1cc is axisymmetric about the second reference plane a2. The second reference plane a2 is parallel to the first main surface 1a, and a distance h1 between the second reference plane a2 and the first main surface 1a is equal to a distance h2 between the second reference plane a2 and the second main surface 1b.

For example, referring to FIG. 3A, the selected side surface 1cc is axisymmetric about the second reference plane a2. That is, portions of the selected side surface 1cc located at both sides of the second reference plane a2 are symmetrical, the second reference plane a2 is parallel to the first main surface 1a, and the distance h1 between the second reference plane a2 and the first main surface 1a is equal to the distance h2 between the second reference plane a2 and the second main surface 1b. That is to say, the second reference plane a2 extends at the middle of the first main surface 1a and the second main surface 1b. Referring to FIG. 3A, the second reference plane a2 is perpendicular to the first reference plane a1.

In some embodiments, referring to FIG. 3A, a maximum vertical distance s between an intersection line of the selected side surface 1cc and the second reference plane a2 and the first reference plane is in a range of 40 μm to 50 μm, inclusive.

It can be understood that the intersection line of the selected side surface 1cc and the second reference plane a2 is a position of the selected side surface 1cc furthest away from the first reference plane a1. The setting of the value range of the vertical distances between the intersection line of the selected side surface 1cc and the second reference plane a2 and the first reference plane may reflect the degree of the selected side surface 1cc protruding from the first reference plane a1. The greater the vertical distance s, the greater the degree of the selected side surface 1cc protruding from the first reference plane a1. The vertical distance s may be 40 μm, 45 μm or 50 μm.

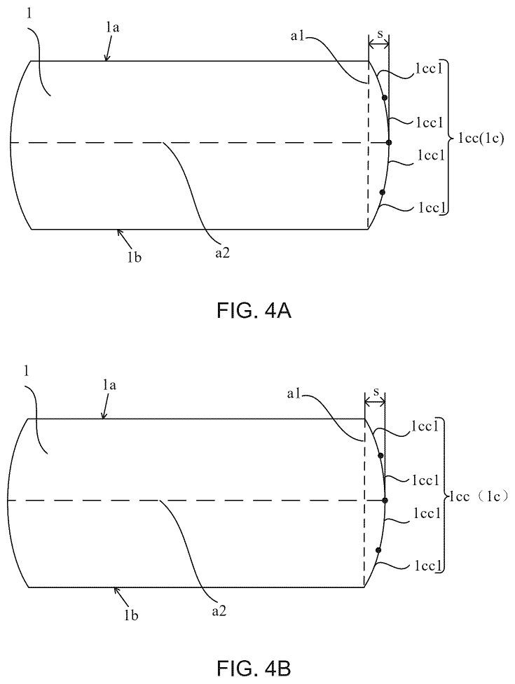

In some embodiments, referring to FIGS. 4A and 4B, the plurality of side surfaces 1c are all selected side surfaces 1cc.

It will be noted that the backplane 1 includes two groups of opposite side surfaces 1c. FIG. 4A is a sectional view obtained by taking along a direction perpendicular to the first main surface and perpendicular to boundary edges of the first main surface and a group of opposite side surfaces. FIG. 4B is a sectional view obtained by taking along a direction perpendicular to the first main surface and perpendicular to boundary edges of the first main surface and another group of opposite side surfaces. It can be seen that each group of opposite side surfaces in the sectional view protrudes toward opposite directions. In a case where the plurality of side surfaces 1c are all selected side surfaces 1cc, the plurality of side surfaces 1c all protrude toward a side away from the first main surface 1a and the second main surface. Each side surface 1c in the plurality of side surfaces 1c has structural features and effects as described for the above selected side surface 1cc, and details are not described again here.

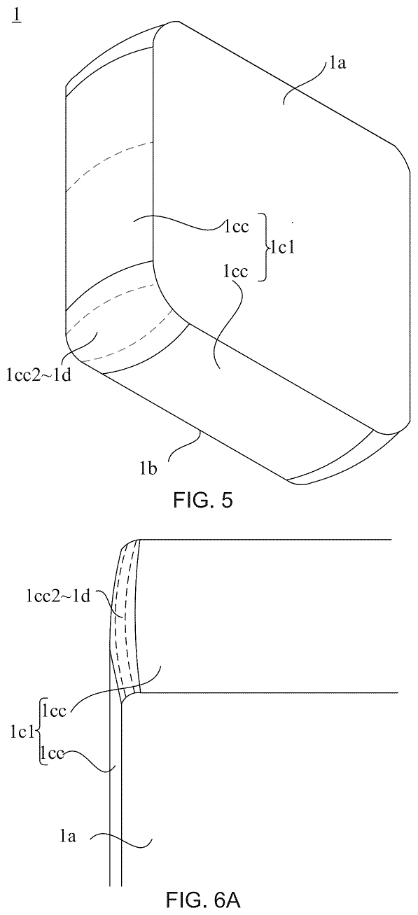

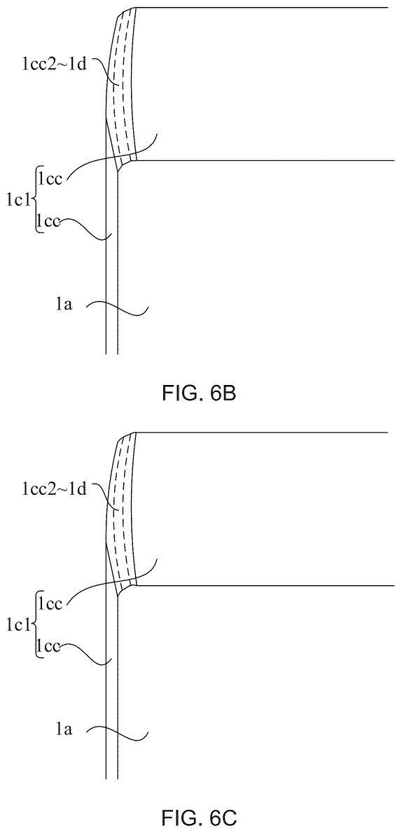

In some embodiments, referring to FIGS. 5 and 6A to 6C, FIG. 5 is a three-dimensional structural diagram of the backplane 1, and FIGS. 6A to 6C are each a partial enlarged view of the three-dimensional structural diagram of the backplane in FIG. 5. Referring to FIG. 5, each two adjacent side surfaces 1c is a group of side surfaces 1c1, and two side surfaces 1c of at least one group of side surfaces 1c1 are connected by a transition side surface 1d. Referring to FIGS. 6A to 6C, the transition side surface 1d is composed of a plurality of second sub-surfaces 1cc2 connected in sequence. The plurality of second sub-surfaces 1cc2 have the same curvature. Alternatively, each second sub-surface 1cc2 in the plurality of second sub-surfaces 1cc2 is a plane. Alternatively, a part of second sub-surfaces 1cc2 in the plurality of second sub-surfaces 1cc2 are planes, and another part of second sub-surfaces 1cc2 in the plurality of second sub-surfaces 1cc2 are curved surfaces.

In some embodiments, a ratio of areas of any two second sub-surfaces is in a range of 0.5 to 2, inclusive; further, it may be in a range of 0.9 to 1.1, inclusive.

For example, referring to FIG. 6A, the transition side surface 1d is composed of a plurality of second sub-surfaces 1cc2 connected in sequence, and the plurality of second sub-surfaces 1cc2 have the same curvature. Then, the formed transition side surface 1d is a curved surface of smooth transition to connect two side surfaces 1c of a group of side surfaces 1c1.

For example, referring to FIG. 6B, each second sub-surface 1cc2 in the plurality of second sub-surfaces 1cc2 is a plane. For example, the number of the second sub-surfaces 1cc2 is three, the three second sub-surfaces 1cc2 are connected in sequence, and the transition side surface 1d connects two side surfaces 1c of a group of side surfaces 1c1 through three second sub-surfaces 1cc2 connected in sequence. An included angle between two adjacent second sub-surfaces 1cc2 is greater than 135°. In two side surfaces 1c of a group of side surfaces 1c1, an included angle between each side surface 1c and a second sub-surface 1cc2 connected to the side surface 1c is greater than 135°, so that the two side surfaces 1c of the group of side surfaces 1c1 are connected in a smooth transition.

For example, referring to FIG. 6C, a part of second sub-surfaces 1cc2 in the plurality of second sub-surfaces 1cc2 are planes, and another part of second sub-surfaces 1cc2 in the plurality of second sub-surfaces 1cc2 are arc surfaces. For example, referring to FIG. 6C, the number of the second sub-surfaces 1cc2 is three, two second sub-surfaces 1cc2 connected to two side surfaces 1c of a group of side surfaces 1c1 are curved surfaces, and the other second sub-surfaces 1cc2 is a plane. The transition side surface 1d connects the two side surfaces 1c of the group of side surfaces 1c1 through a curved surface, a plane and another curved surface connected in sequence.

The above arrangement of the transition side surface 1d may make transition of two side surfaces 1c of a group of side surfaces 1c1 gentle, thereby enhancing strength of side edges of the backplane and reducing collision and edge chipping and corner chipping caused by excessive concentration of stress on the edges. Moreover, in the subsequent process of forming the plurality of connecting lines and the protective layer (e.g., an ink material), the ink material may be well attached to the surface of the backplane to form the protective layer, so as to reduce loss of the ink material, thereby improving production efficiency and enhancing the reliability of the display panel.

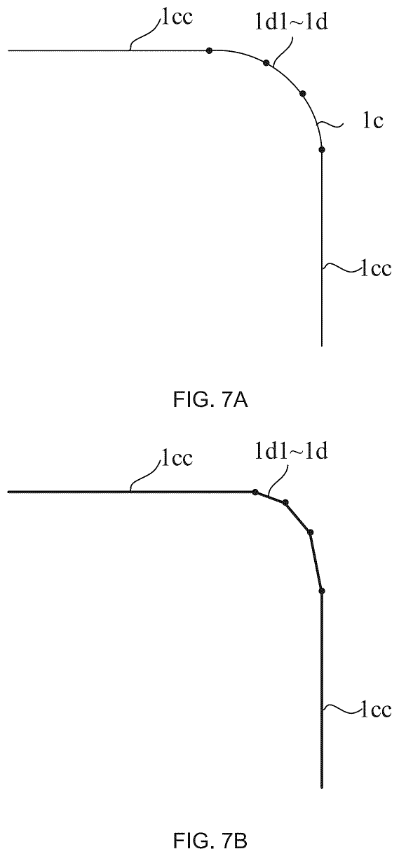

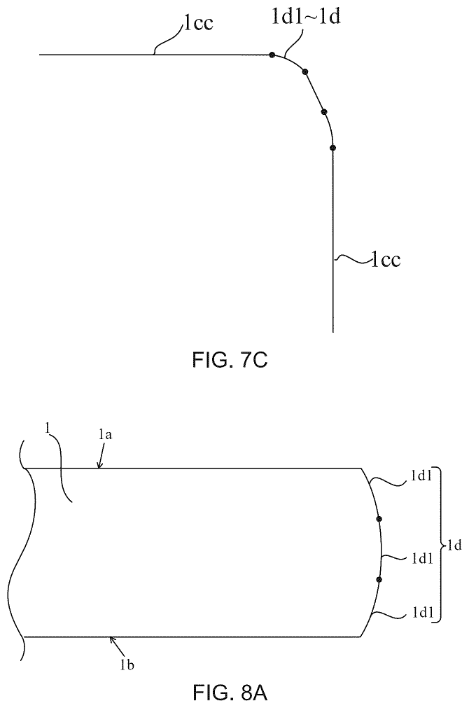

In some embodiments, referring to FIGS. 7A to 7C, FIGS. 7A to 7C are each a partial enlarged view of the orthographic projection of the backplane 1 on the first main surface 1a, and the shape of the orthographic projection of the transition side surface 1d on a plane where the first main surface 1a is located is a plurality of sub-segments 1d1 connected in sequence. Each sub-segment 1d1 in the plurality of sub-segments 1d1 is a curved segment. Alternatively, each sub-segment 1d1 in the plurality of sub-segments 1d1 is a line segment. Alternatively, a part of sub-segments 1d1 in the plurality of sub-segments 1d1 are curved segments, and another part of sub-segments 1d1 in the plurality of sub-segments 1d1 are line segments. For example, the shape of the first main surface 1a and the second main surface 1b of the backplane 1 is a rounded rectangle.

For example, referring to FIG. 7A, each sub-segment 1d1 in the plurality of sub-segments 1d1 is a curved segment. The plurality of curved segments have the same curvature, and an orthographic projection of the formed transition side surface 1d on the plane where the first main surface 1a is located is in a shape of a curved line, so as to enable a smooth transition between two side surfaces 1c of a group of side surfaces 1c1.

For example, referring to FIG. 7B, each sub-segment 1d1 in the plurality of sub-segments 1d1 is a line segment. For example, the number of the sub-segments 1d1 in FIG. 7B is three, and the three sub-segments 1d1 are connected in sequence, so as to enable a smooth transition between two side surfaces 1c of a group of side surfaces 1c1.

For example, referring to FIG. 7C, a part of sub-segments 1d1 in the plurality of sub-segments 1d1 are curved segments, and another part of sub-segments 1d1 in the plurality of sub-segments 1d1 are line segments. For example, the number of the sub-segments 1d1 in FIG. 7C is three, and the three sub-segments 1d1 are connected in sequence. Two sub-segments 1d1 connected to two side surfaces 1c of a group of side surfaces 1c1 are curved segments, and the other sub-segment 1d1 is a line segment. The transition side surface 1d connects the two side surfaces 1c of the group of side surfaces 1c1 through a curved segment, a line segment and another curved segment connected in sequence, so as to enable a smooth transition between the two side surfaces 1c of the group of side surfaces 1c1.

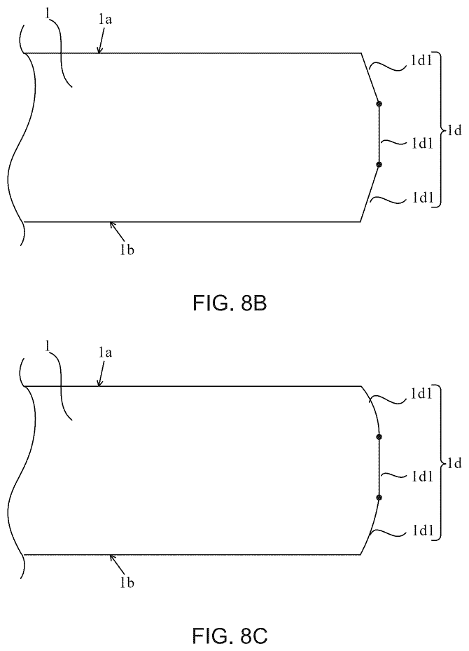

In some embodiments, referring to FIGS. 8A to 8C, FIGS. 8A to 8C are each a sectional view showing a structure of the backplane 1 taken along a direction perpendicular to a diagonal line of the first main surface 1a. The shape of the transition side surface 1d obtained by making a cross-section perpendicular to the first main surface 1a and along a diagonal line of the first main surface 1a is a plurality of sub-segments 1d1 connected in sequence. Each sub-segment 1d1 in the plurality of sub-segments 1d1 is a curved segment. Alternatively, each sub-segment 1d1 in the plurality of sub-segments 1d1 is a line segment. Alternatively, a part of sub-segments in the plurality of sub-segments 1d1 are curved segments, and another part of sub-segments 1d1 in the plurality of sub-segments 1d1 are line segments.

For example, referring to FIG. 8A, an orthographic projection of the transition side surface 1d on a cross-section in a direction perpendicular to a diagonal line of the first main surface 1a is a plurality of sub-segments 1d1 connected in sequence. The plurality of sub-segments 1d1 are a plurality of curved segments with the same curvature, and the plurality of curved segments are connected in sequence to form a smooth curve, that is, the orthographic projection of the plurality of curved segments on this section is in a curved shape. In this way, two side surfaces 1c of a group of side surfaces 1c1 may be smoothly connected by the transition side surface 1d, so as to reduce collision caused by excessive concentration of stress on the edges, thereby reducing the breakage rate of the display panel and enhancing the reliability of the display panel.

It will be noted that the plurality of curved segments of the orthographic projection of the transition side surface 1d on the cross-section taken in a direction perpendicular to the first main surface 1a and along the diagonal line of the first main surface 1a have the same curvature as the plurality of curved segments obtain in the orthographic projection of the transition side surface 1d on the plane where the first main surface 1a is located, that is, the degrees of curvature are the same.

For example, each sub-segment 1d1 in the plurality of sub-segments 1d1 is a line segment. For example, the number of the sub-segments 1d1 in FIG. 8B is three, and the three sub-segments 1d1 are connected in sequence, so as to enable a smooth transition between two side surfaces 1c of a group of side surfaces 1c1.

For example, a part of sub-segments 1d1 in the plurality of sub-segments 1d1 are curved segments, and another part of sub-segments 1d1 in the plurality of sub-segments 1d1 are line segments. For example, the number of the sub-segments 1d1 in FIG. 8C is three, and the three sub-segments 1d1 are connected in sequence. Two sub-segments 1d1 connected to two side surfaces 1c of a group of side surfaces 1c1 are curved segments, and the other sub-segment 1d1 is a line segment. The transition side surface 1d connects the two side surfaces 1c of the group of side surfaces 1c1 through a curved segment, a line segment and another curved segment connected in sequence, so as to enable a smooth transition between the two side surfaces 1c of the group of side surfaces 1c1.

The above arrangement of the transition side surface 1d may make transition of two side surfaces 1c of a group of side surfaces 1c1 gentle, thereby enhancing strength of side edges of the backplane and reducing collision and edge chipping and corner chipping caused by excessive concentration of stress on the edges. Moreover, in the subsequent process of forming the plurality of connecting lines and the protective layer (e.g., an ink material), the ink material may be well attached to the surface of the backplane to form the protective layer, so as to reduce loss of the ink material, thereby improving production efficiency and enhancing the reliability of the display panel.

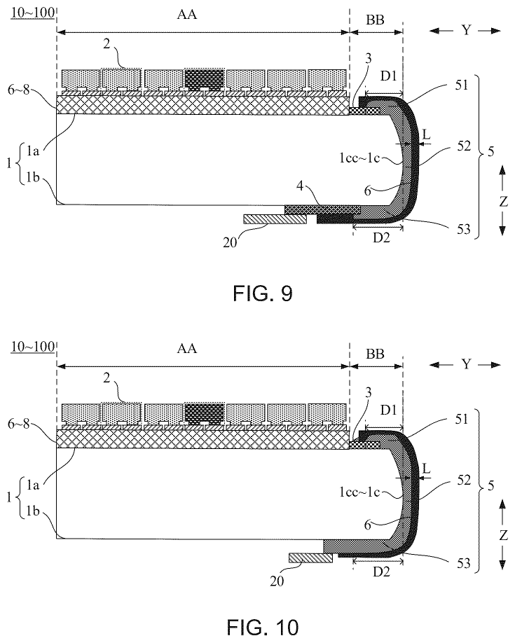

In some embodiments, referring to FIG. 9, the display panel 10 further includes a plurality of second electrodes 4 disposed on the second main surface 1b of the backplane 1, and the plurality of second electrodes 4 are configured to be electrically connected to a driver chip or a flexible circuit board. Each connecting line 5 in the plurality of connecting lines 5 is electrically connected to a second electrode 4 in the plurality of second electrodes 4.

For example, the plurality of second electrodes 4 are disposed on the second main surface 1b of the backplane 1 and are configured to be electrically connected to the driver chip or the flexible circuit board, that is, the plurality of second electrodes 4 are used to be bonded to the driver chip or the flexible circuit board. In some examples, the second main surface 1b of the backplane 1 has a bonding region. At least some of the plurality of second electrodes 4 are located in the bonding region, and the plurality of second electrodes are electrically connected to the driver chip or the flexible circuit in the bonding region, and are electrically connected to the driver chip or the flexible circuit by connecting wiring. Therefore, the driver chip or the flexible circuit board may be disposed on the back of the display panel and is electrically connected to the front of the display panel 10 through the plurality of second electrodes 4, the plurality of connecting lines 5 and the plurality of first electrodes 3, thereby controlling the light-emitting device 2 to emit light to achieve display.

For example, referring to FIG. 1, the plurality of second electrodes 4 are arranged at intervals in the first direction X and provided proximate to the selected side surface 1cc. The number of the plurality of second electrodes 4 is consistent with the number of the plurality of connecting lines 5. An end of each connecting line 5 is electrically connected to a first electrode 3, and another end of each connecting line 5 is electrically connected to a second electrode 4. The plurality of first electrodes 3 and the plurality of second electrodes 4 may be connected in one-to-one correspondence by the plurality of connecting lines 5, so as to achieve transmission of signals.

For example, referring to FIG. 9, the plurality of first electrodes 3 and the plurality of second electrodes 4 extend in a direction (e.g., the second direction Y shown in FIG. 9) perpendicular to the selected side surface 1cc of the backplane 1. A dimension D1 of each first electrode 3 in the plurality of first electrodes 3 in the second direction Y is less than a dimension D2 of each second electrode 4 in the plurality of second electrodes 4 in the second direction Y. The plurality of first electrodes 3 are located in the peripheral region BB of the first main surface 1a, and the orthographic projection of the plurality of second electrodes 4 on the first main surface 1a of the backplane 1 extends to the display region AA.

In some embodiments, as shown in FIG. 9, an orthographic projection of a portion of each connecting line 5 located on the second main surface 1b on the second main surface 1b at least partially overlaps with an orthographic projection of the second electrode 4 electrically connected to the connecting line 5 on the second main surface 1b. That is, the connecting line 5 covers a portion of the corresponding second electrode 4. In this way, each connecting line 5 and the second electrode 4 have a large contact area, so that the connecting line 5 and the second electrode 4 may achieve full contact, thereby being conducive to transmission of signals.

In some embodiments, as shown in FIG. 10, portions of the plurality of connecting lines 5 located on the second main surface 1b of the backplane 1 are configured to be bonded to the driver chip or the flexible circuit board. That is, the display panel 10 does not include a plurality of second electrodes, and the driver chip and the flexible circuit board in the display apparatus 100 are directly bonded to the portions of the plurality of connecting lines 5 located on the second main surface 1b of the backplane 1, so that the driver chip or the flexible circuit board may be disposed on the back of the display panel 10 and electrically connected to the front of the display panel 10 by the plurality of connecting lines 5 and the plurality of first electrodes 3, thereby controlling the light-emitting device 2 to emit light to achieve display.

The above solution of using the plurality of connecting lines 5 to directly bond to the driver chip or flexible circuit board may save the production of the plurality of second electrodes 4, simplify the manufacturing process of the display panel 10, and improve the manufacturing efficiency. Moreover, contact resistance generated between the plurality of second electrodes 4 and the plurality of connecting lines 5 may be avoided, thereby being beneficial to transmission of electrical signals.

Some embodiments of the present disclosure further provide a display apparatus 100. As shown in FIGS. 9 and 10, the display apparatus 100 includes a display panel 10 and a driver chip 20. The driver chip 20 is disposed on the second main surface 1b of the backplane 1 of the display panel 10. The driver chip 20 is electrically connected to the plurality of connecting lines 5 in the display panel 10.

In some embodiments, referring to FIG. 9, in a case where the display panel 10 further includes a plurality of second electrodes 4, the plurality of second electrodes 4 are electrically connected to the plurality of connecting lines 5 respectively. The driver chip 20 is electrically connected to the plurality of second electrodes 4, so as to be electrically connected to the plurality of connecting lines 5 by the plurality of second electrodes 4. It can be understood that the thickness of the second electrode 4 at a position bonded to the driver chip 20 may be equal to the thickness of the second electrode 4 at other positions; alternatively, the thickness of the second electrode 4 at the position bonded to the driver chip 20 may be smaller than the thickness of the second electrode 4 at other positions.

In some other embodiments, as shown in FIG. 10, in a case where the display panel 10 does not include a plurality of second electrodes 4, the driver chip 20 is directly electrically connected to portions of the plurality of connecting lines 5 located on the second main surface 1b of the backplane 1. It can be understood that the thickness of the connecting line 5 at a position bonded to the driver chip 20 may be equal to the thickness of the connecting line 5 at other positions; alternatively, the thickness of the connecting line 5 at the position bonded to the driver chip 20 may be smaller than the thickness of the connecting line 5 at other positions.

Beneficial effects that can be achieved by the display apparatus 100 in the above embodiments of the present disclosure are the same as beneficial effects that can be achieved by the above display panel 10, and details are not repeated here.

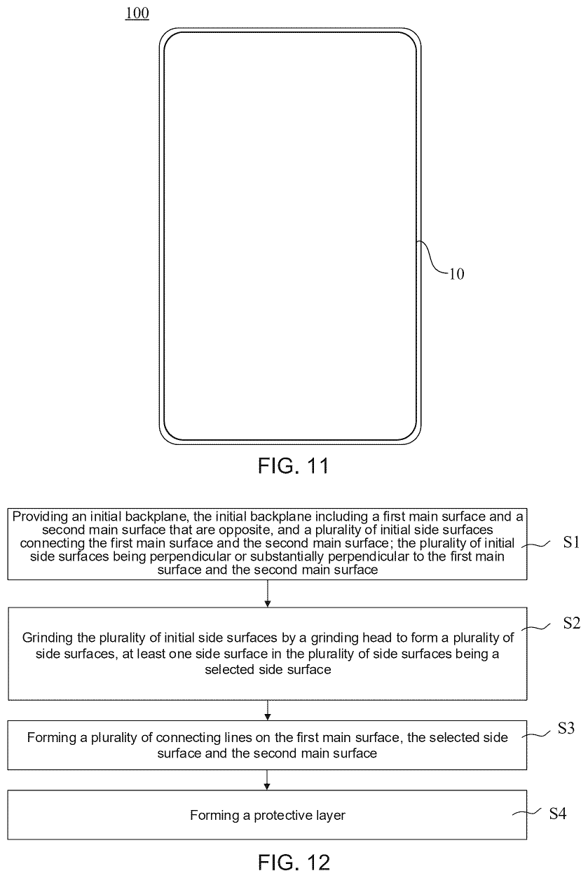

In some embodiments, referring to FIG. 11, the display apparatus 100 may be a mini LED display apparatus or a micro LED display apparatus.

The display apparatus 100 may be any apparatus that displays images whether in motion (e.g., a video) or stationary (e.g., a still image), and regardless of text or image. More specifically, it is expected that the embodiments may be implemented in or associated with a variety of electronic devices, and the variety of electronic devices may include (but are not limited to), for example, mobile phones, wireless devices, personal digital assistants (PDAs), hand-held or portable computers, global positioning system (GPS) receivers/navigators, cameras, MPEG-4 Part 14 (MP4) video players, video cameras, game consoles, watches, clocks, calculators, TV monitors, flat-panel displays, computer monitors, car displays (e.g., odometer displays), navigators, cockpit controllers and/or displays, camera view displays (e.g., display of rear view camera in vehicles), electronic photos, electronic billboards or signs, projectors, architectural structures, packaging and aesthetic structures (e.g., displays for displaying an image of a piece of jewelry), etc.

Some embodiments of the present disclosure provide a method for manufacturing a display panel. The manufacturing method is used to manufacture the display panel mentioned above. As shown in FIG. 12, the manufacturing method includes following steps.

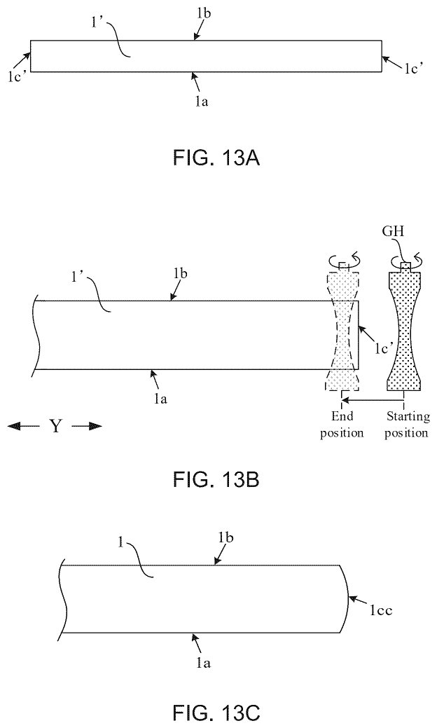

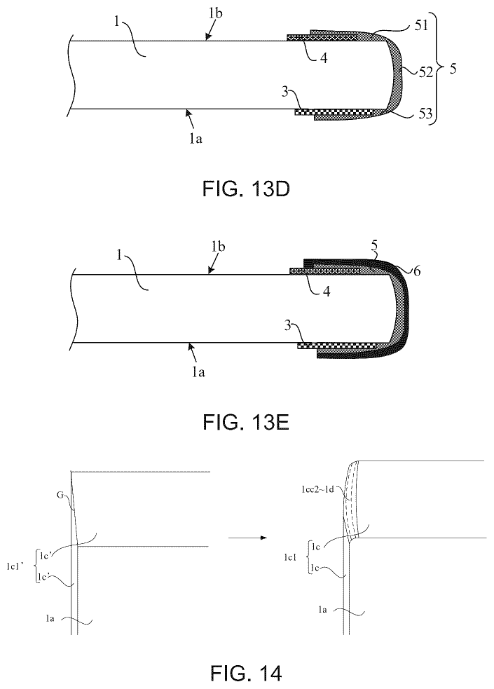

In S1, an initial backplane 1′ is provided. As shown in FIG. 13A, the initial backplane 1′ includes a first main surface 1a and a second main surface 1b that are opposite, and a plurality of initial side surfaces 1c′ connecting the first main surface 1a and the second main surface 1b. The plurality of initial side surfaces 1c′ are perpendicular or substantially perpendicular to the first main surface 1a and the second main surface 1b.

For example, the above initial backplane 1′ refers to a substrate with a driving circuit layer. The initial backplane 1′ includes a base and a driving circuit layer disposed on a surface of the base. A surface of the driving circuit layer away from the base is the first main surface 1a. The above base is, for example, a glass base. It will be noted that the first main surface 1a and the second main surface 1b of the initial backplane are consistent with the first main surface 1a and the second main surface 1b of the final backplane 1. A right angle is formed between two adjacent initial side surfaces of the initial backplane 1′, a right angle is formed between the first main surface 1a and the initial side surface, and a right angle is formed between the second main surface and the initial side surface. The two adjacent initial side surfaces 1c′ of the initial backplane 1′ are a group of initial side surfaces 1c1′.

In S2, as shown in FIGS. 13B and 13C, the plurality of initial side surfaces 1c′ are ground by a grinding head GH to form a plurality of side surfaces 1c, and at least one side surface 1c in the plurality of side surfaces 1c is a selected side surface 1cc.

In some embodiments, the specific grinding process step for forming a side surface 1c includes that, as shown in FIG. 13B, in a process of the grinding head GH moving horizontally in the second direction Y from a starting position facing the initial side surface and at a certain distance away from the initial side surface to an end position at a constant speed, the grinding head GH itself rotates at a high speed with a certain rate, thereby obtaining the side surface 1c of a specific surface shape (e.g., a curved surface).

The selected side surface 1cc protrudes from a first reference plane a1, the first reference plane a1 is a plane and is connected to and adjacent to the first main surface 1a and the second main surface 1b. The selected side surface 1cc is composed of a plurality of first sub-surfaces 1cc1 connected in sequence. The plurality of first sub-surfaces 1cc1 have the same curvature. Alternatively, each first sub-surface 1cc1 in the plurality of first sub-surfaces 1cc1 is a plane. Alternatively, a part of first sub-surfaces 1cc1 in the plurality of first sub-surfaces 1cc1 are planes, and another part of first sub-surfaces 1cc1 in the plurality of first sub-surfaces 1cc1 are curved surfaces.

It will be noted that in the plurality of side surfaces 1c formed by grinding the plurality of initial side surfaces 1c′ here, the number of the ground side surfaces 1c may be one, two, three or four, and at least one of the ground side surfaces 1c is used as the selected side surface 1cc. A smooth transition connection may be achieved between the first main surface 1a and the second main surface 1b of the backplane after grinding.

For the specific structure and the function of the selected side surface, reference may be made to the description in the previous part, and details are not repeated here.

In S3, referring to FIG. 13D, a plurality of connecting lines 5 are formed on the first main surface 1a, the selected side surface 1cc and the second main surface 1b.

For example, the plurality of connecting lines 5 are arranged side by side and at intervals. Each connecting line in the plurality of connecting lines includes a first segment of line 51, a second segment of line 52 and a third segment of line 53 connected in sequence. The first segment of lines 51 are disposed on the first main surface 1a, the second segment of lines 52 are disposed on at least one side surface 1c in the plurality of side surfaces 1c, and the third segment of lines 53 are disposed on the second main surface 1b.

It will be understood that the second segment of lines 52 are provided on at least one side surface 1c in the plurality of side surfaces 1c, which means that the second segment of lines 52 may be provided on one side surface 1c, two side surfaces 1c, three side surfaces 1c or four side surfaces 1c.

In S4, referring to FIG. 13E, a protective layer 6 is formed.

For example, the protective layer 6 is at least disposed on the selected side surface 1cc, and regions of the first main surface 1a and the second main surface 1b proximate to the selected side surface 1cc.

It will be noted that the protective layer 6 is configured to protect the selected side surface 1cc, and the regions of the first main surface 1a and the second main surface 1b proximate to the selected side surface 1cc, so as to avoid collision and damage to the above regions during subsequent processes.

In some embodiments, the manufacturing process of S2 mentioned above further includes following step.

In S2′, referring to FIGS. 5 and 14, a boundary edge G of two adjacent initial side surfaces 1c′ in at least one group of initial side surfaces 1c′ is ground to form a transition side surface 1d.

For example, each two adjacent initial side surfaces 1c′ are a group of initial side surfaces 1c1′, and a boundary edge G of the two initial side surfaces 1c′ in at least one group of side surfaces 1c1′ is ground to form the transition side surface 1d. The two adjacent side surfaces 1c are connected by the transition side surface 1d. The transition side surface 1d is composed of a plurality of second sub-surfaces 1cc2 connected in sequence. The plurality of second sub-surfaces 1cc2 have the same curvature. Alternatively, each second sub-surface 1cc2 in the plurality of second sub-surfaces 1cc2 is a plane. Alternatively, a part of second sub-surfaces 1cc2 in the plurality of second sub-surfaces 1cc2 are planes, and another part of second sub-surfaces 1cc2 in the plurality of second sub-surfaces 1cc2 are curved surfaces.

In some examples, four side surfaces of the formed backplane are all selected side surfaces. In this grinding step, a grinding rod is used to grind all around the entire initial backplane 1′ along the grinding path, that is, simultaneously grind four initial side surfaces of the initial backplane and edges between two adjacent initial side surfaces. The backplane 1 obtained after grinding is reduced in size overall compared to the initial backplane. That is, the four initial side surfaces 1c′ of the initial backplane 1′ are ground away to form the four selected side surfaces of the backplane. A right-angled edge between the two adjacent initial side surfaces of the initial backplane is ground away to form the transition side surface 1d.

For the above specific structure and the function of the transition side surface 1d, reference may be made to the description in the previous part, and details are not repeated here.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display panel, comprising:
a backplane, the backplane including a first main surface and a second main surface that are opposite, and a plurality of side surfaces connecting the first main surface and the second main surface; wherein at least one side surface in the plurality of side surfaces is a selected side surface, the selected side surface protrudes from a first reference plane, and the first reference plane is a plane and is connected to and adjacent to the first main surface and the second main surface; the selected side surface is composed of a plurality of first sub-surfaces connected in sequence; and the plurality of first sub-surfaces satisfy one of: the plurality of first sub-surfaces have same curvature; each first sub-surface in the plurality of first sub-surfaces is a plane; and a part of first sub-surfaces in the plurality of first sub-surfaces are planes, and another part of first sub-surfaces in the plurality of first sub-surfaces are curved surfaces;
a plurality of connecting lines, the plurality of connecting lines being disposed side by side and at intervals; wherein each connecting line in the plurality of connecting lines includes a first segment of line, a second segment of line and a third segment of line that are connected in sequence; first segment of lines of the plurality of connecting lines are disposed on the first main surface, second segment of lines of the plurality of connecting lines are disposed on the selected side surface, and third segment of lines of the plurality of connecting lines are disposed on the second main surface; and
a protective layer, the protective layer being at least disposed on the selected side surface and regions of the first main surface and the second main surface proximate to the selected side surface.

2. The display panel according to claim 1, wherein the selected side surface is a curved surface, and a central angle corresponding to the curved surface is in a range of 30° to 35°, inclusive.

3. The display panel according to claim 1, wherein each first sub-surface in the plurality of first sub-surfaces is a plane; the selected side surface includes at least four planes connected in sequence, a plane connected to the first main surface is a first connection plane, and a plane connected to the second main surface is a second connection plane; an angle between the first connection plane and the adjacent first main surface is greater than 135°, an angle between two adjacent planes of the selected side surface is greater than 135°, and an angle between the second connection plane and the adjacent second main surface is greater than 135°.

4. The display panel according to claim 2, wherein the selected side surface is axisymmetric about a second reference plane, the second reference plane is parallel to the first main surface, and a distance between the second reference plane and the first main surface is equal to a distance between the second reference plane and the second main surface.

5. The display panel according to claim 4, wherein a maximum vertical distance between an intersection line of the selected side surface and the second reference plane and the first reference plane is in a range of 40 μm to 50 μm, inclusive.

6. The display panel according to claim 1, wherein the plurality of side surfaces are all selected side surfaces.

7. The display panel according to claim 6, wherein each two adjacent side surfaces is a group of side surfaces, and two side surfaces of at least one group of side surfaces are connected by a transition side surface; the transition side surface is composed of a plurality of second sub-surfaces connected in sequence; the plurality of second sub-surfaces have same curvature; or each second sub-surface in the plurality of second sub-surfaces is a plane; or a part of second sub-surfaces in the plurality of second sub-surfaces are planes, and another part of second sub-surfaces in the plurality of second sub-surfaces are curved surfaces.

8. The display panel according to claim 7, wherein a shape of an orthographic projection of the transition side surface on a plane where the first main surface is located is a plurality of sub-segments connected in sequence; each sub-segment in the plurality of sub-segments is a curved segment; or each sub-segment in the plurality of sub-segments is a line segment; or a part of sub-segments in the plurality of sub-segments are curved segments, and another part of sub-segments in the plurality of sub-segments are line segments.

9. The display panel according to claim 8, wherein a shape of the transition side surface obtained by taking a cross-section perpendicular to the first main surface and along a diagonal line of the first main surface is a plurality of sub-segments connected in sequence; each sub-segment in the plurality of sub-segments is a curved segment; or each sub-segment in the plurality of sub-segments is a line segment; or a part of sub-segments in the plurality of sub-segments are curved segments, and another part of sub-segments in the plurality of sub-segments are line segments.

10. The display panel according to claim 1, wherein the protective layer further covers the plurality of connecting lines, and the protective layer is disposed on a side of the plurality of connecting lines away from the backplane.

11. The display panel according to claim 10, wherein a thickness of the protective layer is in a range of 1.7 μm to 1.8 μm, inclusive.

12. The display panel according to claim 1, further comprising:
a plurality of first electrodes disposed on the first main surface, wherein the plurality of first electrodes being disposed proximate to the selected side surface, and each connecting line is electrically connected to a first electrode in the plurality of first electrodes; and
a plurality of light-emitting devices disposed on the first main surface of the backplane, wherein the plurality of light-emitting devices are electrically connected to the plurality of first electrodes.

13. The display panel according to claim 12, further comprising;
a plurality of second electrodes disposed on the second main surface of the backplane; wherein the plurality of second electrodes are configured to be electrically connected to a driver chip or a flexible circuit board; and each connecting line in the plurality of connecting lines is electrically connected to a second electrode in the plurality of second electrodes.

14. A display apparatus, comprising:
the display panel according to claim 1; and
a driver chip, wherein the driver chip is disposed on the second main surface of the backplane in the display panel, and the driver chip is electrically connected to the plurality of connecting lines in the display panel.

15. A method for manufacturing a display panel, comprising:
providing an initial backplane, the initial backplane includes a first main surface and a second main surface that are opposite, and a plurality of initial side surfaces connecting the first main surface and the second main surface, wherein the plurality of initial side surfaces are perpendicular or substantially perpendicular to the first main surface and the second main surface;
grinding the plurality of initial side surfaces to form a plurality of side surfaces; wherein at least one side surface in the plurality of side surfaces is a selected side surface, the selected side surface protrudes from a first reference plane, and the first reference plane is a plane and is connected to and adjacent to the first main surface and the second main surface; the selected side surface is composed of a plurality of first sub-surfaces connected in sequence; and the plurality of first sub-surfaces satisfy one of the plurality of first sub-surfaces have same curvature; each first sub-surface in the plurality of first sub-surfaces is a plane; and a part of first sub-surfaces in the plurality of first sub-surfaces are planes, and another part of first sub-surfaces in the plurality of first sub-surfaces are curved surfaces;
forming a plurality of connecting lines on the first main surface, the selected side surface and the second main surface, wherein the plurality of connecting lines are disposed side by side and at intervals; each connecting line in the plurality of connecting lines includes a first segment of line, a second segment of line and a third segment of line that are connected in sequence; first segment of lines the plurality of connecting lines are disposed on the first main surface, second segment of lines of the plurality of connecting lines are disposed on the selected side surface, and third segment of lines of the plurality of connecting lines are disposed on the second main surface; and
forming a protective layer, wherein the protective layer is at least disposed on the selected side surface and regions of the first main surface and the second main surface proximate to the selected side surface.

16. The method for manufacturing the display panel according to claim 15, wherein in a process of grinding the plurality of initial side surfaces, a boundary edge of two adjacent initial side surfaces in at least one group of initial side surfaces is ground to form a transition side surface; two adjacent side surfaces are connected by the transition side surface, and the transition side surface is composed of a plurality of second sub-surfaces connected in sequence; the plurality of second sub-surfaces have same curvature; or each second sub-surface in the plurality of second sub-surfaces is a plane; or a part of second sub-surfaces in the plurality of second sub-surfaces are planes, and another part of second sub-surfaces in the plurality of second sub-surfaces are curved surfaces.

17. The display panel according to claim 3, wherein the selected side surface is axisymmetric about a second reference plane, the second reference plane is parallel to the first main surface, and a distance between the second reference plane and the first main surface is equal to a distance between the second reference plane and the second main surface.

18. The display panel according to claim 17, wherein a maximum vertical distance between an intersection line of the selected side surface and the second reference plane and the first reference plane is in a range of 40 μm to 50 μm, inclusive.

19. The display panel according to claim 1, wherein a ratio of areas of any two first sub-surfaces is in a range of 0.5 to 2, inclusive.

20. The display panel according to claim 7, wherein a ratio of areas of any two second sub-surfaces is in a range of 0.5 to 2, inclusive.
